(19) United States
(12) Patent Application Publication
(10) Pub. No.: US 2006/0071346 A1
(43) Pub. Date: Apr. 6, 2006

(54) Semiconductor device and manufacturing method thereof

(76) Inventor: Atsushi Watanabe, Sakata (JP)

Correspondence Address: HARNESS, DICKEY & PIERCE, P.L.C., P.O. BOX 828, BLOOMFIELD HILLS, MI, 48303, US

(21) Appl. No.: 11/224,709

(22) Filed: Sep. 12, 2005

(30) Foreign Application Priority Data
Oct. 5, 2004 (JP) 2004-292210

(51) Int. Cl. H01L 23/48

(52) U.S. Cl. 257/778

(57) ABSTRACT

A semiconductor device, includes: a circuit board having an inner terminal on one surface, an outer terminal on the other surface, and wiring between the inner terminal and the outer terminal; a semiconductor chip flip-chip bonded to the inner terminal against the circuit board; and a sealing resin covering the semiconductor chip and having a side portion of a diced surface that is the same as a side portion of the circuit board.

### BACKGROUND OF THE INVENTION

1. Technical Field

The present invention relates to a semiconductor device and a method for manufacturing the same, in which a semiconductor element flip-chip bonded to a circuit board is sealed with a resin.

2. Related Art

Recently, products such as portable equipment are becoming increasingly multi-functional at the same time they are shrinking in size. Naturally, there are demands for miniaturizing the semiconductor parts inside these products and for downsizing the mounting area. A chip size package (CSP) is one of these products mounted on a wiring substrate within its limited space. The CSP utilizes a double-sided or multilayered wiring circuit board, and an IC chip is flip-chip bonded to one surface of the board, while an outer terminal is provided on the other surface of the board (e.g., see Issued Japanese Patent 3332555, p. 5 and FIG. 4).

For the CSP, underfill (sealant) is used in the flip-chip bonding portion between the circuit board and the IC chip. Thus, after curing the underfill, a fillet is formed. The fillet is formed, from a viewpoint of protecting the flip-chip bonding portion, when it flows over the edges of the IC chip and runs along the edges of the circuit board. Therefore, the circuit board in general is made much larger than the IC chip.

The conventional CSP uses the underfill (sealant) in the flip-chip bonding portion between the circuit board and the IC chip. Thus, a fillet is formed after the underfill has been cured. The fillet has a role of protecting the flip-chip bonding portion. However, it is very likely that the fillet includes voids. Accordingly, for the fillet to serve its role, it is important to broaden the region for the fillet to flow by keeping the edges of the circuit board away from the flip-chip bonding portion of the IC chip. As a consequence, the circuit board must be much larger than the IC chip, and this inhibits the miniaturization of the IC package.

### SUMMARY

An advantage of the present invention is to provide a semiconductor device and a method therefor which enable further miniaturization of the IC package.

According to an aspect of the invention, a semiconductor device includes: a circuit board having an inner terminal on one surface, an outer terminal on the other surface, and wiring between the inner terminal and the outer terminal; a semiconductor chip flip-chip bonded to the inner terminal against the circuit board; and a sealing resin covering the semiconductor chip and having a side portion of a diced surface that is the same as a side portion of the circuit board.

According to another aspect of the invention, a semiconductor device includes: a circuit board having an inner terminal on one surface, an outer terminal on the other surface, and wiring between the inner terminal and the outer terminal; a semiconductor chip flip-chip bonded to the inner terminal against the circuit board; a filling auxiliary member provided at least between a central region of the semiconductor chip and the circuit board; and a sealing resin covering the semiconductor chip and having a side portion of a diced surface that is the same as a side portion of the circuit board.

In these cases, each of the semiconductor device of the invention, by covering the semiconductor chip with the sealing resin, contributes to easy handling and improving reliability. The sealing resin has the side surface sharing the same surface with the side portion of the circuit board while suppressing voids. Accordingly, the flip-chip bonding portion is sufficiently protected at the same time the package is miniaturized. Further, for the semiconductor device having the filling auxiliary member, the filling auxiliary member can help with the penetration of the sealing resin into areas where the sealing resin does not easily penetrate.

Further, in order to obtain the downsized semiconductor package with improved handling convenience and reliability, it is preferable that the semiconductor device of the invention further include any of the following characteristics:

the sealing resin is a molding resin diced together with the circuit board;

the sealing resin is penetrated into a gap surround by the inner terminals and between the circuit board and the opposing semiconductor chip;

a portion where the semiconductor chip and the circuit board are flip-chip bonded has a metal junction configuration;

an external angle between the other surface of the circuit board and a side surface region stretching from the side portion of the circuit board to the sealing resin is smaller than 90°;

the filling auxiliary member includes an adhesive in a form of film or paste; and

the filling auxiliary member includes a shrink-and-cure type adhesive.

According to yet another aspect of the invention, a method for manufacturing the semiconductor device includes: preparing each circuit board which is composed of an inner terminal on one surface, an outer terminal on the other surface, and wiring between the inner terminal and the outer terminal and which has a plurality of flip-chip bonding regions; flip-chip bonding a predetermined number of semiconductor chips to the inner terminals upon positioning the semiconductor chips at the flip-chip bonding regions; conducting molding by covering the circuit board with a die for holding the predetermined number of semiconductor chips and by pressuring the sealing resin into the die; and dicing the circuit board and the sealing resin in a single process.

In this case, the sealing resin is formed after the molding process. In addition, in this molding process, the sealing resin is pressured into the die, whose one unit is the circuit board to which the predetermined number of semiconductor chips are flip-chip bonded. One unit of a cured mold is cut into separate semiconductor packages by dicing. These molding and dicing processes contribute to protection of the flip-chip bonding portion and to miniaturization of the package. Further, the sealing resin that covers the semiconductor chip improves handling convenience and reliability.

In order to obtain the downsized semiconductor package with improved handling convenience and reliability, it is preferable that the method for manufacturing the semiconductor device of the invention further include any of:

adding an electrode member before or after the dicing, since the outer terminal on the circuit board is incomplete prior to the molding;

attaching protection tape to the outer terminal side when preparing the circuit board;

carrying out the flip-chip bonding by metal junction.

in the molding process, providing a plurality of press fit holes for the sealing resin in the die and penetrating the sealing resin into the gap surrounded by the inner terminals and between the circuit board and the opposing semiconductor chip;

prior to the flip-chip bonding process, providing in advance a filling auxiliary member for the sealing resin against the circuit board at the center of each flip-chip bonding region surrounded by the inner terminals; and

in the dicing process, dicing the side surface region stretching from the side surface of the circuit board to the sealing resin by use of a dicing blade having an edge in a tapered configuration so that an angle of the side surface region to the other surface of the circuit board is larger than 90°.

### BRIEF DESCRIPTION OF THE DRAWINGS

The invention will be described with reference to the accompanying drawings, wherein like numbers refer to like elements and wherein:

FIG. 1 is a cross sectional diagram showing an essential part of a semiconductor device of a first embodiment.

FIG. 2 is a first cross sectional diagram showing a method for manufacturing the semiconductor device of a second embodiment in an order of the process.

FIG. 3 is a second cross sectional diagram following FIG. 2.

FIG. 4 is a third cross sectional diagram following FIG. 3.

FIG. 5 is a cross sectional diagram showing an essential part of the method for manufacturing the semiconductor device of a third embodiment.

FIG. 6 is a cross sectional diagram showing a realized essential part of the semiconductor device, following FIG. 5.

FIG. 7 is a cross sectional diagram showing the essential part of the semiconductor device of a fourth embodiment.

FIG. 8 is a first cross sectional diagram showing the method for manufacturing the semiconductor device of a fifth embodiment in an order of the process.

FIG. 9 is a second cross sectional diagram following FIG. 8.

FIG. 10 is a third cross sectional diagram following FIG. 9.

FIG. 11 is a cross sectional diagram showing the essential part of the method for manufacturing the semiconductor device of a sixth embodiment.

FIG. 12 is a cross sectional diagram showing a realized essential part of the semiconductor device, following FIG. 11.

FIG. 13 is a diagram outlining a first example of a molding die used in the invention.

FIG. 14 is a diagram outlining a second example of a molding die used in the invention.

### DESCRIPTION OF THE EMBODIMENTS

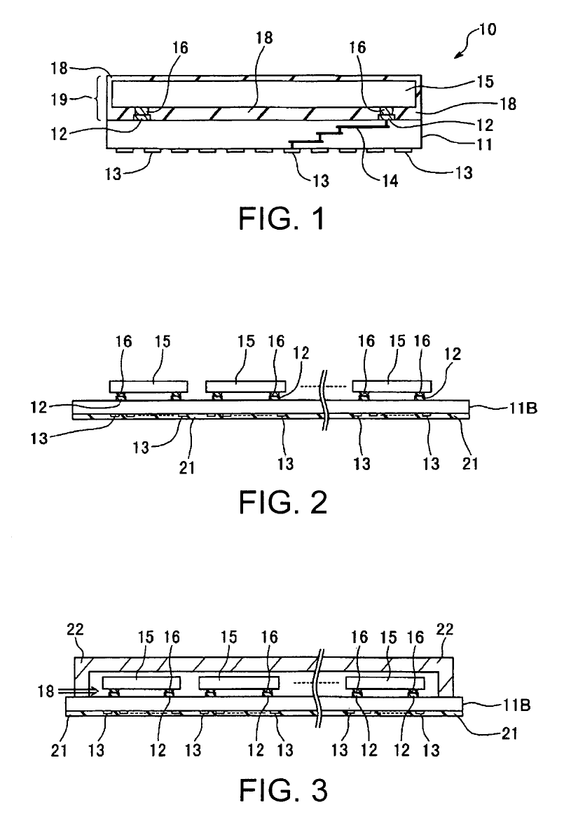

FIG. 1 is a cross sectional diagram showing an essential part of the semiconductor device of the first embodiment of the invention. A semiconductor package 10 has a structure as follows. A circuit board 11 is an organic multilayer wiring substrate and includes inner terminals 12 on one surface and outer terminals 13 on the other surface. The inner terminals 12 and the outer terminals 13 are connected by multilayer wiring 14 interposed therebetween. The inner terminals 12 are conductive patterns plated with Au, for example. Alternatively, the inner terminals 12 may be composed by Sn plating or solder plating with Sn—Cu, Sn—Ag, Sn—Ag—Cu, or the like. The outer terminals 13 are conductive patterns including lands, for example. Alternatively, the outer terminals 13 may be composed of ball electrodes or of other bump electrodes.

A semiconductor chip 15 has bump electrodes 16 on its primary surface and is flip-chip bonded to the inner terminals 12 against the circuit board 11. The bump electrodes 16 are Au bumps, for example, and are joined by Au—Au metal junction with the corresponding Au-plated patterns of the inner terminals 12. Also, the bump electrodes 16 may be solder bumps or may be chosen from any bump electrodes suitable for the junction with the inner terminals 12.

A sealing resin 18 covers the semiconductor chip 15 and includes a side portion 19 of a diced surface that is the same as a side portion of the circuit board 11. The sealing resin 18 is penetrated into a gap surrounded by the inner terminals 12 and between the circuit board 11 and the opposing semiconductor chip 15, thereby realizing a protective and void-suppressed configuration. The sealing resin 18 is a molding resin, for example, and is diced together with the circuit board 11.

According to the structure of the first embodiment, the sealing resin 18 can improve the handling convenience and reliability by covering the semiconductor chip 15. It is a configuration in which the underfill of the conventional chip size package (CSP) is replaced by the molding resin, namely, the sealing resin 18. The sealing resin 18 has the side portion 19 sharing the same surface with the side portion of the circuit board 11 while suppressing the voids by use of the molding resin. Consequently, the size of the circuit board 11 can approach the size of the semiconductor chip 15. That is, the flip-chip bonding portion can be protected at the same time the package size can be reduced.

FIG. 2 to FIG. 4 are cross sectional diagrams each showing an essential part of the method for manufacturing the semiconductor device of the second embodiment of the invention in the order of the process and showing a procedure for enabling the structure of FIG. 1. FIG. 2 to FIG. 4 are explained using the same reference numbers for the same elements as those used in FIG. 1.

As shown in FIG. 2, a circuit board 11B having a plurality of flip-chip bonding regions is prepared. The circuit board 11B is an organic multilayer wiring substrate and includes the inner terminals 12 on one surface and the outer terminals 13 on the other surface. The inner terminals 12 are each plated with Au for flip-chip bonding. Further, the other surface of the circuit board 11B having the outer terminals 13 formed thereon is protected by protection tape 21 attached thereto. The outer terminals 13 are not in the complete configuration at this point, and the electrode members may be added in the subsequent process.

Next, a predetermined number of the semiconductor chips 15 having the bump electrodes 16 on their primary surfaces are positioned for flip-chip bonding at the respective regions and flip-chip bonded to the inner terminals 12. In this case, the bump electrodes 16 are Au bumps and are joined by Au—Au metal junction with the corresponding inner terminals 12 of the circuit board 11 by reacting the Au-plated patterns of the inner terminals 12 with supersonic vibration. It is preferable that a width of the gap between the circuit board 11 and the opposing semiconductor chip 15 be 50 μm or more so that the sealing resin can easily penetrate thereinto. Thus, it is important to adjust the height of the bump electrodes 16. In this case, the gap of about 70 μm-100 μm is formed between the circuit board 11 and the opposing semiconductor chip 15.

Next, as shown in FIG. 3, the circuit board 11B is covered by a molding die 22 for holding the predetermined number of the semiconductor chips 15. Then, the sealing resin 18 is pressured into the die 22 at a high temperature (150° C. or more). The sealing resin 18 is a heat-curable epoxy resin, for example, containing preferably 30 μm or less amount of ball-shaped filler by 50 to 80 wt % whose particles have even-sized diameters.

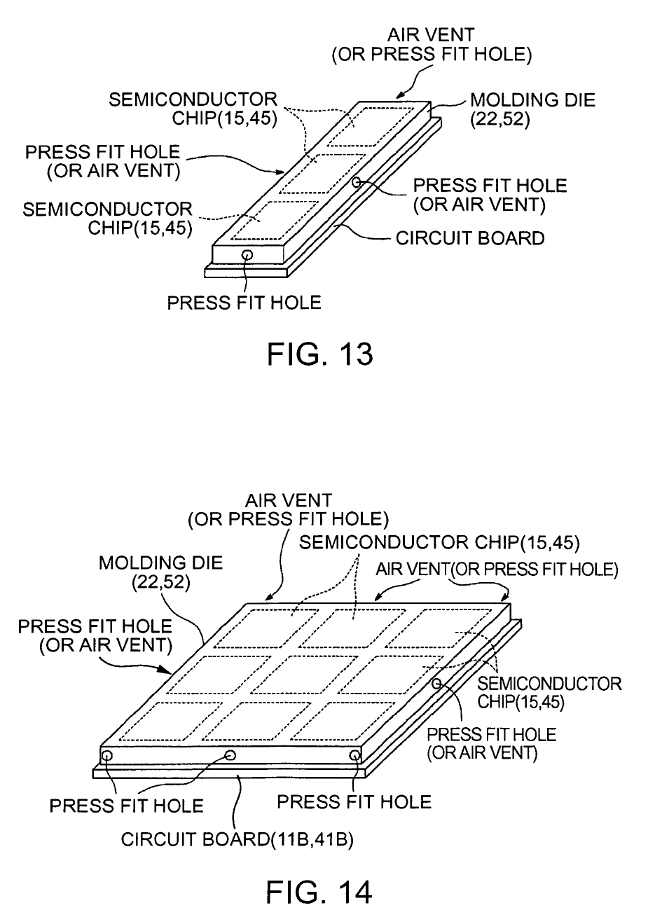

Further, it is important that the molding die 22 is large enough to match the size of the circuit board 11B but has a structure to let the sealing resin 18 to successfully fill therein. For example, the molding die 22 may have a structure that fits the circuit board 11B holding the semiconductor chips 15 in a row (see FIG. 13) or in matrix (see FIG. 14). Although not shown in the drawings, a diameter of an air vent is set to be smaller than that of a press fit hole. The air vents and press fit holes for the sealing resin may be provided at a suitable number of places. Accordingly, the sealing resin 18 is pressured into the die 22, whose one unit is the circuit board 11B to which the predetermined number of semiconductor chips 15 are flip-chip bonded.

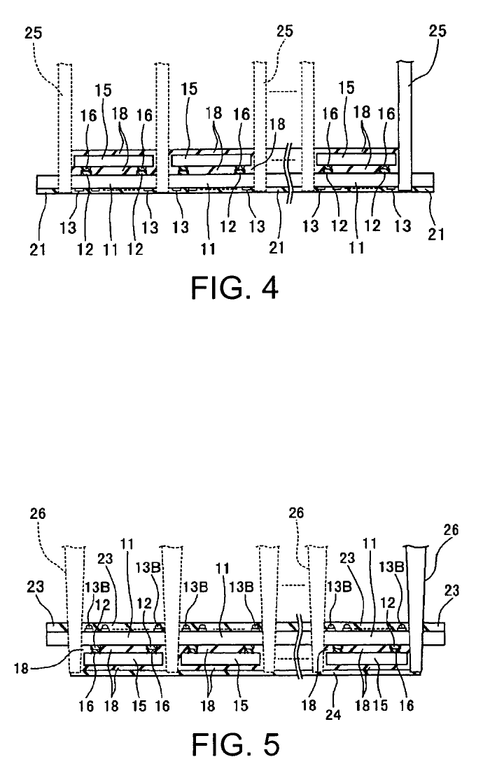

Next, as shown in FIG. 4, after curing, a mold with the cured sealing resin 18 is taken out from the die 22. One unit of the mold holding the predetermined number of semiconductor chips 15 undergoes the dicing process. For the dicing, a dicing blade 25 is used, for example. The dicing may be carried out with the side of the circuit board 11B facing down or the side of the circuit board 11B facing up. The protection tape is provided at least on the surface facing down. In this case, the dicing is carried out with the side of the circuit board 11B facing down and supported by use of the protection tape 21. The protection tape may be attached to both sides of the circuit board 11B and the molding resin (18) for dicing. As a result of this dicing process, the mold is diced into the circuit boards 11, yielding the semiconductor packages 10 as shown in FIG. 1.

According to the second embodiment, the sealing resin 18 is formed after the molding process. Moreover, in the molding process, the sealing resin 18 is pressured into the die 22, whose one unit is the circuit board 11B to which the predetermined number of semiconductor chips 15 are flip-chip bonded. That is, the molding resin (18) substitutes the underfill. As a consequence, the flip-chip bonding portion includes hardly any voids. One unit of the mold is cut into separate semiconductor packages 10 by undergoing the dicing process. Although it depends on dicing precision, the pitch of the semiconductor chips 15 to be mounted on the circuit board 11B can be narrowed. These molding and dicing processes contribute to sufficient protection of the flip-chip bonding portion as well as to miniaturization of the package. As a result, in comparison to the conventional CSP, the size of the circuit board 11 can further approach the size of the semiconductor chip 15. Further, the sealing resin 18 covers the semiconductor chip 15, thereby improving the handling convenience and reliability.

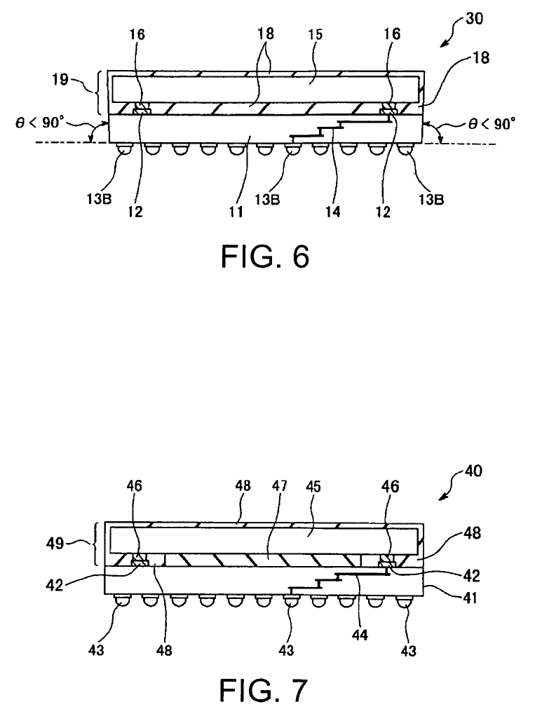

FIGS. 5 and 6 are cross sectional diagrams each showing the essential part of the method for manufacturing the semiconductor device and the semiconductor device of the third embodiment and showing a procedure for forming a working example having a modified structure of FIG. 1. FIGS. 5 and 6 are explained using the same reference numbers for the same elements as those used in FIG. 1.

The same processes as in the second embodiment are carried out up to FIG. 3. Thereafter, as shown in FIG. 5, after the curing, the mold of the cured sealing resin 18 is taken out from the die. Then, the electrode members, that is, ball electrodes 13B in this case, are further added to the outer terminals 13. After that, protection tape 23 is attached to the side of the circuit board 11B. Also, protection tape 24 is attached to the side of the sealing resin 18. Next, the dicing process is carried out with the side of the sealing resin 18 facing down and supported. For the dicing, a dicing blade 26 having, for example, a predetermined tapered configuration is used. Accordingly, the dicing is conducted so that the tapered configuration of the blade 26 reflects on the diced surface.

As shown in FIG. 6, a semiconductor package 30 having the circuit board 11 separated by the above-described dicing process has the following characteristic. That is, the side surface region stretching from the side surface of the circuit board 11 to the side portion 19 of the sealing resin 18 is diced with the dicing blade 26 having an edge in the tapered configuration in a manner that an angle between the side surface region and the surface of the circuit board 11 is slightly larger than 90°. As a consequence, an external angle θ between the surface of the circuit board 11 and the side surface region stretching from the side portion of the circuit board 11 to the sealing resin 18 is slightly smaller than 90°.

According to the method and structure of the third embodiment, the sealing resin 18 contributes, through molding and dicing, to sufficient protection of the flip-chip bonding portion while suppressing the voids, and to further miniaturization of the package. Further, the semiconductor package 30 has a shape of an inverted trapezoid due to the slight tapered configuration of the side surface region stretching from the side portion of the circuit board 11 to the sealing resin 18. As a result, the semiconductor chip 15 is covered with the sealing resin 18 and is hardly exposed, thereby contributing to reliability and managing convenience such as handling.

FIG. 7 is a cross sectional diagram showing the essential part of the semiconductor device of the fourth embodiment of the invention. A semiconductor package 40 has a structure as follows. A circuit board 41 is an organic multilayer wiring substrate and includes inner terminals 42 on one surface and outer terminals 43 on the other surface. The inner terminals 42 and the outer terminals 43 are connected by multilayer wiring 44 interposed therebetween. The inner terminals 42 are conductive patterns plated with Au, for example. Alternatively, the inner terminals 42 may be composed by Sn plating or solder plating with Sn—Cu, Sn—Ag, Sn—Ag—Cu, or the like. As for the composition of the outer terminals 43, ball electrodes are arranged such as in ball grid array (BGA). Alternatively, the outer terminals 43 may be composed simply as lands or as other bump electrodes.

A semiconductor chip 45 has bump electrodes 46 on its primary surface and is flip-chip bonded to the inner terminals 42 against the circuit board 41. There is a filling auxiliary member 47 between the central region of the semiconductor chip 45 and the circuit board 41. The filling auxiliary member 47 is an adhesive in a form of film, for example. Alternatively, the filling auxiliary member 47 may be an adhesive in a form of paste. Either way, it is preferable that the filling auxiliary member 47 include a shrink-and-cure type adhesive.

The bump electrodes 46 are Au bumps, for example, and are joined by Au—Au metal junction with the corresponding Au-plated patterns of the inner terminals 42. Alternatively, the bump electrodes 46 may be solder bumps or chosen from any bump electrodes suitable for the junction with the inner terminals 42.

A sealing resin 48 covers the semiconductor chip and has a side portion 49 of the diced surface that is the same as the side portion of the circuit board 41. The sealing resin 48 is penetrated into the gap surrounded by the inner terminals 42 and between the circuit board 41 and the opposing semiconductor chip 45 and adheres to the filling auxiliary member 47, thereby realizing the protective and void-suppressed configuration. The sealing resin 48 is the molding resin, for example, and is diced together with the circuit board 41.

According to the structure of the fourth embodiment above, the same effect as in the first embodiment can be exerted. That is, the structure in which the underfill of the conventional CSP is replaced by the molding resin, namely, the sealing resin 48, can be obtained. The sealing resin 48 can improve the handling convenience and reliability by covering the semiconductor chip 45. The filling auxiliary member 48 helps the sealing resin 48 with the filling by being disposed in the region between the circuit board 41 and the opposing semiconductor chip 45 where it is relatively difficult for the sealing resin 48 to get filled into. The sealing resin 48 has the side portion 49 sharing the same surface with the side portion of the circuit board 41 while suppressing the voids by the molding resin. As a consequence, the size of the circuit board 41 can approach the size of the semiconductor chip 45. That is, the flip-chip bonding portion can be protected at the same time the package size can be reduced.

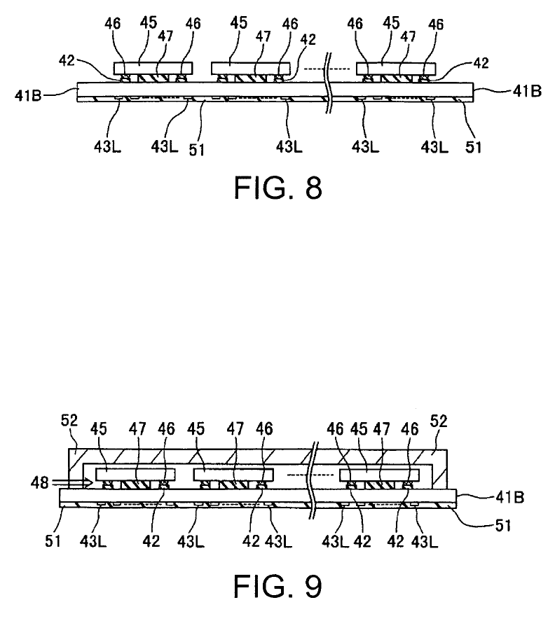

FIG. 8 to FIG. 10 are cross sectional diagrams showing the essential part of the method for manufacturing the semiconductor device of the fifth embodiment in the order of the process and showing the procedure for realizing the structure of FIG. 7. FIG. 8 to FIG. 10 are explained using the same reference numbers for the same elements as those used in FIG. 7.

As shown in FIG. 8, a circuit board 41B having the plurality of flip-chip bonding regions is prepared. The circuit board 41B is an organic multilayer wiring substrate and includes the inner terminals 42 on one surface and the outer terminals 43L on the other surface. The inner terminals 42 are each plated with Au for flip-chip bonding. Further, the other surface of the circuit board 41B having the outer terminals 43B formed thereon is protected by protection tape 51 attached thereto. The outer terminals 43L are land patterns and are not in the complete configuration at this point. The electrode members (ball electrodes) are to be added in the subsequent process.

Next, on the circuit board 41B, the filling auxiliary member 47 is filled in each of the regions surrounded by the inner terminals 42. As the filling auxiliary member 47, the shrink-and-cure type adhesive in a form of resin film is used. Then, the predetermined number of the semiconductor chips 45 having the bump electrodes 46 on their primary surfaces are positioned at the flip-chip bonding regions and flip-chip bonded to the inner terminals 42 on the circuit board 41B. In this case, the bump electrodes 46 are the Au bumps and are joined by Au—Au metal junction with the corresponding inner terminals 42 of the circuit board 41 by reacting the Au-plated patterns of the inner terminals 42 with supersonic vibration. It is preferable that the width of the gap between the circuit board 41 and the opposing semiconductor chip 45 be 50 μm or more. Further, the filling auxiliary member 47 is provided so as to help the sealing resin with the penetration. It is important to adjust the height of the bump electrode 46. In this case, the gap of about 70 μm to 100 μm is formed between the circuit board 41 and the opposing semiconductor chip 45 so as to enable the adhesion by use of the filling auxiliary member 47 and the reliable Au—Au metal junction.

Next, as shown in FIG. 9, the circuit board 41B is covered by a molding die 52 for holding the predetermined number of semiconductor chips 45. Then, the sealing resin 48 is pressured into the die 52 at a high temperature (150° C. or more). The sealing resin 48 is a heat-curable epoxy resin, for example, containing preferably 30 μm or less amount of ball-shaped filler by 50 to 80 wt % whose particles have even-sized diameters. The filling auxiliary member 47 helps the sealing resin 48 penetrate into the gap between the circuit board 41 and the opposing semiconductor chip 45.

Further, it is important that the molding die 52 is large enough to match the size of the circuit board 41B but has a structure to let the sealing resin 48 to successfully fill therein. For example, the molding die 52 may have a structure that fits the circuit board 41B holding the semiconductor chips 45 in a row (see FIG. 13) or in matrix (see FIG. 14.) Although not shown in the drawings, the diameter of an air vent is to be smaller than that of a press fit hole. The air vents and the press fit holes for the sealing resin may be provided at a suitable number of places. Accordingly, the sealing resin 48 is pressured into the die 52, whose one unit is the circuit board 41B to which the predetermined number of semiconductor chips 45 are flip-chip bonded.

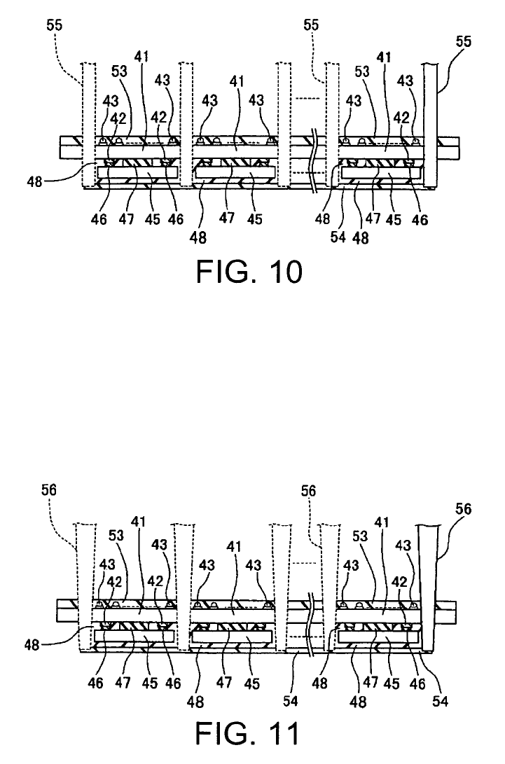

Next, as shown in FIG. 10, after the curing, a mold with the cured sealing resin 48 is taken out from the die 52. Then, the protection tape 51 is peeled off, and the electrode members, that is, the ball electrodes in this case, are coupled to the outer terminals 43L to form the outer terminals 43. Thereafter, protection tape 53 is attached to the side of these outer terminals 43L. Also, protection tape 54 is attached to the side of the sealing resin 48. Next, the dicing process is carried out with the side of the sealing resin 48 facing down and supported. For the dicing, a dicing blade 55 is used, for example. Alternatively, the attachment of the protection tape 53 may be omitted. As a result of this dicing process, the mold is diced into the circuit boards 41, yielding the semiconductor packages 40 as shown in FIG. 7.

According to the fourth embodiment, the sealing resin 48 is formed after the molding process. Moreover, in the molding process, the sealing resin 48 is pressured into the die 52, whose one unit is the circuit board 41B to which the predetermined number of semiconductor chips 45 are flip-chip bonded. The filling auxiliary member 47 is filled between the circuit board 47 and the opposing semiconductor chip 45 and helps the sealing resin 48 with the penetration. By such a molding process, the sealing resin 48 substitutes the underfill. As a consequence, the flip-chip bonding portion hardly includes the voids. One unit of the mold is cut into separate semiconductor packages 40 by dicing. Although it depends on dicing precision, the pitch of the semiconductor chips 45 to be mounted on the circuit board 41B can be narrowed. These molding and dicing processes contribute to sufficient protection of the flip-chip bonding portion as well as to miniaturization of the package. As a consequence, when compared with the conventional CSP, the size of the circuit board 41 can further approach the size of the semiconductor chip 45. Further, the sealing resin 48 covers the semiconductor chip 45, thereby improving the handling convenience and reliability.

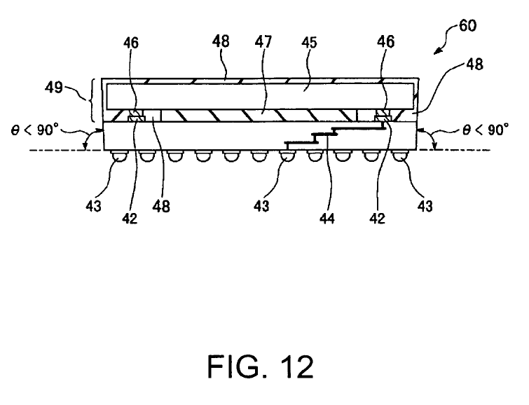

FIGS. 11 and 12 are cross sectional diagrams each showing the essential part of the method for manufacturing the semiconductor device of the sixth embodiment and showing a procedure for forming a working example having a modified structure of FIG. 7. FIGS. 11 and 12 are given with the same reference numbers for the same elements as those used in FIG. 7.

In place of the dicing process in FIG. 10 of the fourth embodiment, a dicing process as shown in FIG. 11 is carried out. For the dicing, a dicing blade 56 having, for example, a predetermined tapered configuration is used. Accordingly, the dicing is conducted so that the tapered configuration of the blade 56 reflects on the diced surface.

As shown in FIG. 12, a semiconductor package 60 having the circuit boards 41 separated by the above-referenced dicing process has the following characteristic. That is, by using the tapered configuration of the edge of the dicing blade 56, the side surface region stretching from the side surface of the circuit board 41 to the side portion 49 of the sealing resin 48 is diced in a manner that the angle between the side surface region and the surface of the circuit board 41 is slightly larger than 90°. As a consequence, the external angle θ between the surface of the circuit board 41 and the side surface region including the side of the circuit board 41 and the side 49 of the sealing resin 48 is slightly smaller than 90°.

According to the method and structure of the sixth embodiment, the sealing resin 48 contributes, though molding and dicing processes and with the additional effect of the filling auxiliary member 47, to sufficient protection of the flip-chip bonding portion while suppressing the voids and to further miniaturization of the package. Further, the semiconductor package 60 has a shape of an inverted trapezoid due to the slight tapered configuration of the side surface region stretching from the side portion of the circuit board 41 to the sealing resin 48. As a result, the semiconductor chip 45 is covered with the sealing resin 48 and is hardly exposed, thereby contributing to the reliability and managing convenience such as handling.

In each of the above-described embodiments, the flip-chip bonding of the semiconductor chip (15 or 45) to the circuit board (11 or 41) is that by the Au—Au metal junction. The Au—Au metal junction makes it easy to ensure the reliability in terms of the strength of the junction itself, the contact resistance, the responsiveness to the narrowing of the pitch, and the weight, temperature, and the like at the time of ultrasonic bonding. However, if a certain extent of compromise in these respects is acceptable, an anisotropic conductive member may be used, or, as described hereinbefore, the soldering may be used for the metal junction.

As thus described, according to the invention, the sealing resin is formed after the molding process and substitutes the underfill in the flip-chip bonding portion. For the semiconductor device including the filling auxiliary member, the filling auxiliary member can help the sealing resin penetrate into the areas where the sealing resin does not easily penetrate. The sealing resin enables easy handling of the semiconductor chip and improves the reliability. In the molding process, the sealing resin is pressured into the die, whose one unit is the circuit board to which the predetermined number of semiconductor chips are flip-chip bonded. One unit of the cured mold is cut into separate semiconductor packages by dicing. As a consequence, the sealing resin has the side portion sharing the same surface with the side portion of the circuit board while suppressing the voids. These molding and dicing processes contribute to the protection of the flip-chip bonding portion and further miniaturization of the package. As a result, it is possible to provide the semiconductor device and the method therefor which enable further miniaturization of the IC package.

What is claimed is:

1. A semiconductor device, comprising:
a circuit board having an inner terminal on one surface, an outer terminal on the other surface, and wiring between the inner terminal and the outer terminal;
a semiconductor chip flip-chip bonded to the inner terminal against the circuit board; and
a sealing resin covering the semiconductor chip and having a side portion of a diced surface that is the same as a side portion of the circuit board.

2. A semiconductor device, comprising:
a circuit board having an inner terminal on one surface, an outer terminal on the other surface, and wiring between the inner terminal and the outer terminal;
a semiconductor chip flip-chip bonded to the inner terminal against the circuit board;
a filling auxiliary member provided at least between a central region of the semiconductor chip and the circuit board; and
a sealing resin covering the semiconductor chip and having a side portion of a diced surface that is the same as a side portion of the circuit board.

3. The semiconductor device according to claim 1, wherein the sealing resin is a molding resin diced together with the circuit board.

4. The semiconductor device according to claim 1, wherein the sealing resin is penetrated into a gap surrounded by the inner terminals and between the circuit board and the opposing semiconductor chip.

5. The semiconductor device according to claim 1, wherein a portion where the semiconductor chip and the circuit board are flip-chip bonded has a metal junction configuration.

6. The semiconductor device according to claim 1, wherein an external angle between the other surface of the circuit board and a side surface region stretching from the side portion of the circuit board to the sealing resin is smaller than 90°.

7. The semiconductor device according to claim 2, wherein the filling auxiliary member includes an adhesive in a form of film or paste.

8. The semiconductor device according to claim 2, wherein the filling auxiliary member includes a shrink-and-cure type adhesive.

9. A method for manufacturing a semiconductor device, comprising:
preparing each circuit board which is composed of an inner terminal on one surface, an outer terminal on the other surface, and wiring between the inner terminal and the outer terminal and which has a plurality of flip-chip bonding regions;
flip-chip bonding a predetermined number of semiconductor chips to the inner terminals upon positioning the semiconductor chips at the flip-chip bonding regions;
conducting molding by covering the circuit board with a die for holding the predetermined number of semiconductor chips and by pressuring the sealing resin into the die; and
dicing the circuit board and the sealing resin in a single process.

10. The method for manufacturing the semiconductor device according to claim 9, further comprising adding an electrode member before or after the dicing, since the outer terminal on the circuit board is incomplete prior to the molding.

11. The method for manufacturing the semiconductor device according to claim 9, further comprising attaching protection tape to the outer terminal side when preparing the circuit board.

12. The method for manufacturing the semiconductor device according to claim 9, further comprising carrying out the flip-chip bonding by metal junction.

13. The method for manufacturing the semiconductor device according to claim 9, further comprising, in the molding process, providing a plurality of press fit holes for the sealing resin in the die and penetrating the sealing resin into the gap surrounded by the inner terminals and between the circuit board and the opposing semiconductor chip.

14. The method for manufacturing the semiconductor device according to claim 9, further comprising, prior to the flip-chip bonding process, providing in advance a filling auxiliary member for the sealing resin against the circuit board at the center of each flip-chip bonding region surrounded by the inner terminals.

15. The method for manufacturing the semiconductor device according to claim 9, further comprising, in the dicing process, dicing a side surface region stretching from the side surface of the circuit board to the sealing resin by use of a dicing blade having an edge in a tapered configuration so that an angle of the side surface region to the other surface of the circuit board is larger than 90°.
